(19) United States
(12) Patent Application Publication
(10) Pub. No.: US 2023/0385482 A1
(43) Pub. Date: Nov. 30, 2023

(54) METHOD FOR SIMULATING A FIRST COMPUTING UNIT IN A SECOND COMPUTING UNIT

(71) Applicant: Robert Bosch GmbH, Stuttgart (DE)

(72) Inventors: Behnaz Pourmohseni, Muenchen (DE); Laura Beermann, Waldbronn (DE); Oliver Kotte, Stuttgart (DE); Sebastian Reiser, Karlsruhe (DE)

(21) Appl. No.: 18/319,117

(22) Filed: May 17, 2023

(30) Foreign Application Priority Data
May 31, 2022 (DE) 10 2022 205 520.9

(51) Int. Cl. G06F 30/20

(52) U.S. Cl. CPC G06F 30/20

(57) ABSTRACT

A method for simulating a first computing unit in a second computing unit, wherein software executed in the first computing unit to be simulated is executed in the second computing unit. The method includes determining, by a scheduling module in the second computing unit, a time schedule according to which processes of the software are processed in the first computing unit to be simulated; executing, by at least one simulation module in the second computing unit, the software for simulating the first computing unit, wherein the at least one simulation module performs a predetermined action at a respective predetermined action time point based on the time schedule, in order to obtain an action result; determining, based on the action result, an action time point of a future, in particular next, action; and using the determined action time point for the time schedule.

### CROSS REFERENCE

The present application claims the benefit under 35 U.S.C. § 119 of German Patent Application No. DE 10 2022 205 520.9 filed on May 31, 2022, which is expressly incorporated herein by reference in its entirety.

### FIELD

The present invention relates to a method for simulating a first computing unit in a second computing unit, and to a computing unit and a computer program for performing said method.

### BACKGROUND INFORMATION

Computing units, for example control devices in (motor) vehicles, can be modeled or simulated in other computing units, such as PCs, for example in that special simulation software simulates the computing unit to be simulated or its functions in the computing unit, for example as a virtual machine. For example, software that the computing unit to be simulated executes in its regular operation can be executed in the computing unit or in the virtual machine as part of the simulation.

### SUMMARY

According to the present invention, a method for simulating a first computing unit in a second computing unit as well as a computing unit and a computer program for performing the method, are provided. Advantageous embodiments of the present invention are disclosed herein.

The present invention provides a possibility to also perform the simulation of the computing unit to be simulated (hereinafter also the first computing unit) as really as possible in terms of the time sequence and to be able to simulate the execution or processing of the software by the first computing unit in terms of the time sequence sufficiently accurately in the simulation. The individual processes of the software are executed as part of the simulation particularly expediently with the same or at least substantially with the same latencies or processing times as in the actual first computing unit. The execution of the software as part of the simulation on the simulation computing unit (hereinafter also second computing unit) thus expediently takes place in a synchronized manner with the execution of the same software in the actual (first) computing unit to be simulated.

In the context of the present description, a distinction is in particular to be made between the terms “computing unit to be simulated” and “simulated computing unit.” The term “computing unit to be simulated” is in particular to be understood to mean the actual, physical unit that is to be simulated digitally, i.e., for example, a control device with a microprocessor/microcontroller (hardware), application software and possibly an operating system (scheduler). Accordingly, the term “simulated computing unit” is to be understood to mean the first computing unit which is digitally or virtually simulated in the second computing unit and thus only exists in software and not as an actual, physical unit.

According to an example embodiment of the present invention, as part of the simulation, software executed in the (first) computing unit to be simulated is executed in the second computing unit. In particular, as part of the simulation in the second computing unit, an actual development platform, comprising hardware unit and operating system (scheduler), is virtually or digitally simulated, for example as a virtual machine, by means of corresponding simulation software. This simulation software is particularly expediently modular in design and has several different software modules.

According to an example embodiment of the present invention, a scheduling module, in particular as a first software module of the simulation software, determines, in the second computing unit, a time schedule according to which processes or tasks or parts, components, or modules of the software are processed in the actual first computing unit to be simulated. The scheduling module thus in particular determines which tasks are executed or fully executed at what time in the first computing unit to be simulated. The schedule describes in particular an order and processing times of the individual software processes during regular operation of the first computing unit. Particularly expediently, the schedule describes when the individual processes are fully processed and when results or outputs of individual processes are available, which in turn may be required as inputs of further processes. The schedule is in particular also dynamic or is produced dynamically in order to be able to respond to changes in a system state (e.g., high rotational speed), for example.

According to an example embodiment of the present invention, preferably, an action module is also used, in particular as a second software module of the simulation software, to determine action events in the second computing unit depending on the time schedule, wherein according to these action events, a predetermined action is to be performed at a respective predetermined action time point as part of the simulation of the first computing unit. Actions may include, for example, reading in data and/or writing data and/or starting the processing of a process. In particular, the action module identifies or determines particular events in the schedule that take place as part of the execution of the software during regular operation of the first computing unit, e.g., the start or end of the processing of individual processes, the exchange of data, the transmission of outputs of individual processes as inputs to further processes, the communication of individual components of the first computing unit with one another, etc. Furthermore, the action module expediently identifies or determines when these individual events occur relative to one another during operation of the first computing unit. Particularly expediently, the action module translates these events that occur as part of the execution of the software during regular operation of the first computing unit into corresponding action events that are to be performed as part of the simulation of the first computing unit.

According to an example embodiment of the present invention, at least one simulation module, in particular in the form of at least one third software module of the simulation software, executes the software in the second computing unit for the simulation or as part of the simulation or as the simulation of the first computing unit. In so doing, the at least one simulation module performs the respective predetermined actions at the predetermined action time points according to the determined action events.

According to an example embodiment of the present invention, several simulation modules may also be provided, wherein each simulation module simulates a particular hardware and/or software component of the first computing unit, for example. Furthermore, for example, each component of the first computing unit may also be simulated by several simulation modules. In particular, the action module is coupled to each such simulation module so that corresponding action events can be individually predetermined for each simulation module.

While such a time schedule generally allows for a more accurate simulation of the real first computing unit, i.e., the first computing unit to be simulated, it is possible during regular operation of the real first computing unit that some action events are necessary at time points that in turn depend on previous action results. Such action results can in particular be output data of the first computing unit to be simulated, such as a rotational speed and/or a crankshaft angle (or corresponding values of these variables) of an internal combustion engine. For example, it is possible that a particular action is to be performed at a particular value of a rotational speed (e.g., of an engine). However, the rotational speed depends in turn on a previous action result, for example.

In light of this, it is provided in the context of the present invention to determine an action time point of a future, in particular next, action based on the action result, and to then use said action time point for the time schedule, i.e., to adjust the time schedule based thereon, for example (this can then take place in the scheduling module). In particular, with said action time point, a next increment, i.e., a next value, can be generated in the schedule. The action time point of the future action can in particular be determined by an extrapolation module in the second computing unit.

The action time point of the future action can also in particular be determined based on an extrapolation logic. Such extrapolation logic can, for example, map an estimated future action, which is, for example, to be angularly synchronous, in the function module to a time point at which the time period between two events need not be constant since the rotational speed may change.

It is also particularly preferred to determine a difference of a time interval between the current action time point and the action time point of the future action, and a time interval between a previous action time point and the current action time point. This difference can then be used for the time schedule, in particular for the adjustment thereof. This preferred variant thus consists in communicating, to the scheduling module (i.e., the time simulation), the difference of the estimated next interval (between the current and the next action) and the last interval (between the current and the previous action). The time simulation can then use this difference, for example, to adjust a stored or saved (and currently used) and, where applicable, periodic interval.

A further advantage of this variant is that the delay that occurs at the start of the simulation due to the unknown/inaccurate occurrence of the first action, i.e., the action time point, is corrected during the runtime. The special case of a fixed periodic action, e.g., no change in the period over the runtime, can continue to be treated with the same implementation as the adjustable or settable periodic actions; the “difference” is then always zero.

Through the modular design of the simulation software in the form of the scheduling module, where applicable of the action module and of the simulation modules as well as, where applicable, of the extrapolation module, individual modules can be particularly simply and flexibly adjusted in order to design the simulation as accurately as possible. According to an example embodiment of the present invention, particularly expediently, the scheduling module is coupled to the simulation modules via the action module and/or the extrapolation module. It is thus possible to particularly simply and flexibly try out different mechanisms in the action module in order to translate the information from the time schedule into specific action events in the software simulation so that the operation of the first computing unit can be simulated as accurately and consistently as possible. In turn, via the extrapolation module, action results can be evaluated, extrapolated, and returned to the time module. This provides a possibility to create an effective, consistent simulation of the first computing unit in an inexpensive and cost-effective manner.

According to an example embodiment of the present invention, advantageously, the timing module determines the time schedule depending on hardware components of the first computing unit to be simulated. As explained, processing times and latencies in the execution of the software in the actual first computing unit can in particular depend on the specific hardware components installed, e.g., on the specifically used processor units or processor cores, storage units, etc. The particular hardware configuration of the first computing unit is expediently taken into account in order to be able to create a time schedule that is as accurate and precise as possible.

The present invention is advantageously suitable for simulating (first) computing units of a variety of different technical fields of application. Particularly advantageously, the first computing unit to be simulated is a control device or a group of control devices, preferably in a (motor) vehicle. Particularly expediently, with the help of the present method, processes in a control device can be simulated with accurate times. For example, the control device may be simulated by a simulation module or by several simulation modules, for example by at least one FMU module (FMU stands for “Functional Mock-up Unit”). For example, when simulating a group of several control devices, each such control device can be modeled by a simulation module or also by several simulation modules, expediently in the form of an FMU module. The individual control devices can each be designed individually, for example, each with a single- or multi-core processor. Furthermore, the individual control devices can in each case be connected to one another via an individual network, e.g., in a wired or wireless manner in each case. Furthermore, individual simulation modules can also be provided to model further vehicle components, e.g., a communication system, e.g., a bus system, or, for example, sensors, actuators, etc.

The first computing unit to be simulated may in particular be a real, actually existing (first) computing unit. For example, the first computing unit may be investigated in the course of the simulation, for example in order to investigate changes to the software of the (first) computing unit in a controlled test scope. Furthermore, the first computing unit to be simulated may also not exist or at least not yet exist in reality. In this case, however, in particular, there is at least one design plan for specific hardware and software components according to which the first computing unit is ultimately to be constructed and operated. For example, the simulation can investigate how design decisions, such as resource allocation or scheduling algorithms, influence the temporal behavior of the overall system.

A computing unit according to the present invention is configured, in particular in terms of program technology, to perform a method according to the present invention. This is in particular the mentioned second computing unit.

The implementation of a method according to the present invention in the form of a computer program or computer program product with program code for performing all method steps is also advantageous since this results in particularly low costs, in particular if an executing control device is also used for further tasks and is therefore present in any event. In the specific case, it is also advantageous that the computing unit to be simulated need not yet be physically present. Lastly, a machine-readable storage medium is provided, on which the computer program is stored as described above. Suitable storage media or data carriers for providing the computer program are in particular magnetic, optical and electrical memories, such as hard disks, flash memory, EEPROMs, DVDs, etc. Downloading a program via computer networks (internet, intranet, etc.) is also possible. Such a download can take place in a wired or cabled or wireless manner (e.g., via a WLAN, a 3G, 4G, 5G, or 6G connection, etc.).

Further advantages and embodiments of the present invention emerge from the description and the figures.

The present invention is illustrated schematically in the drawing on the basis of exemplary embodiments and is described below with reference to the figures.

### BRIEF DESCRIPTION OF THE DRAWINGS

FIG. 1 schematically shows a first computing unit that can be the basis of a preferred embodiment of the method according to the present invention.

FIG. 2 schematically shows a second computing unit configured to perform a preferred embodiment of the method according to the present invention.

FIG. 3 schematically shows a preferred embodiment of the method according to the present invention as a block diagram.

FIG. 4 schematically shows a further preferred embodiment of the method according to the present invention.

### DETAILED DESCRIPTION OF EXAMPLE EMBODIMENTS

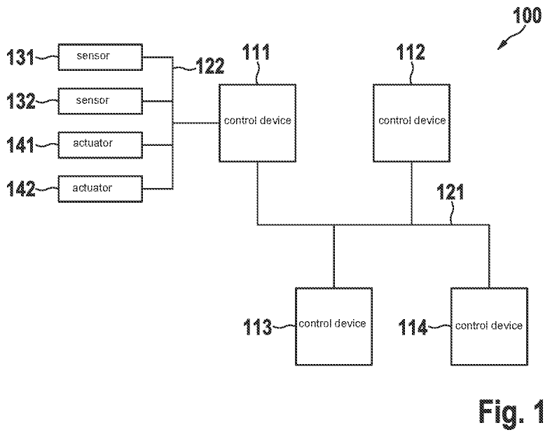

In FIG. 1, a first computing unit is shown schematically and denoted by 100, which is designed as a group of control devices in a (motor) vehicle.

The first computing unit 100 comprises a plurality of control devices 111, 112, 113, 114, which may, for example, be provided for engine control, for transmission control, for controlling driving assistance functions, infotainment systems, etc. Corresponding software is executed in each of the control devices 111, 112, 113, 114 for this purpose.

The control devices 111, 112, 113, 114 can be in data transmission connection to one another via a global communication system 121, for example via a field bus, such as CAN, Ethernet/IP, ProfiNet, Sercos 2, Sercos III, EtherCAT, FlexRay, LIN, MOST, etc.

Individual control devices, for example the control device 111, may furthermore be connected to peripheral devices, such as sensors 131, 132 or actuators 141, 142. For example, the control device 111 may be connected to these peripheral devices via a further, local communication system 122, e.g., a local field bus. It is understood that several or all control devices may each be connected to corresponding peripheral devices. Furthermore, it is understood that the hardware unit 100 may comprise still further control devices and further components.

As part of the simulation, the first computing unit 100 is to be digitally simulated in a second computing unit, for example in order to investigate changes to the software of individual control devices in a controlled test scope. For example, in the simulation, the entire group of all control devices 111, 112, 113, 114 is to be simulated. Alternatively, only individual ones of the control devices or one control device may also be simulated.

In so doing, the software executed during regular operation on the respective control devices 111, 112, 113, 114 to be simulated is to be executed in the simulation with accurate times and consistently, in particular in such a way that software tasks and software processes in the simulation can be processed with the same or at least substantially the same latency as during regular operation of the control devices 111, 112, 113, 114.

For this purpose, the simulation of the first computing unit 100 takes place in the context of a preferred embodiment of a method according to the present invention by means of modularly designed simulation software, as shall be described below.

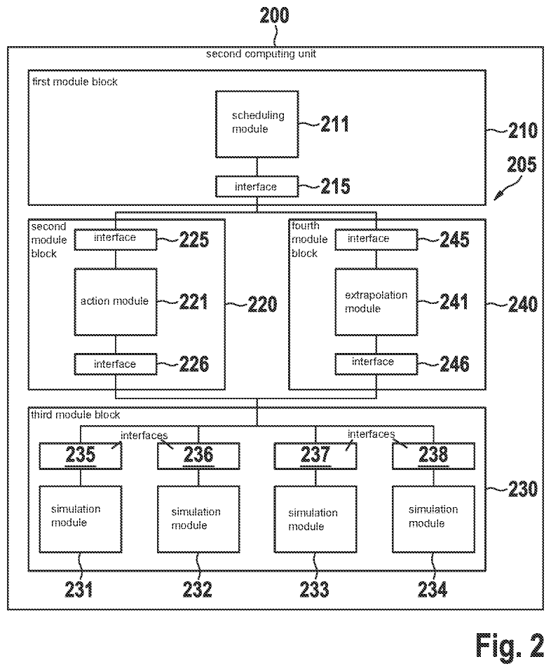

FIG. 2 schematically shows a second computing unit 200, which may, for example, be designed as a PC and which is configured, in particular in terms of program technology, to perform a preferred embodiment of the method according to the present invention. For this purpose, a corresponding modularly designed simulation software 205 is executed in the second computing unit 200.

A first function or module block 210 is provided for the temporal analysis of the software executed in the first computing unit 100 to be simulated. For this purpose, a scheduling module 211 is provided as a first software module of the simulation software 205 and determines a time schedule according to which processes and/or tasks are processed in the first computing unit 100 to be simulated or in the respective control devices 111, 112, 113, 114. This time schedule serves in particular as a time reference for the execution of the software in the course of the simulation.

A second function or module block 220 is provided, for example, to transfer the time schedule to the simulation, in particular to translate particular events of the time schedule into corresponding action events for the simulation. For this purpose, an action module 221 is provided as a second software module of the simulation software 205 and determines action events according to which a predetermined action is to be performed at a respective predetermined action time point in the course of the simulation of the first computing unit 100.

A third function or module block 230 is provided for the actual simulation of the first computing unit 100 and for the execution of the software of the control devices 111, 112, 113, 114 to be simulated. For this purpose, a plurality of simulation modules 231, 232, 233, 234 are provided, each executing the software of the first computing unit 100. For example, each of the simulation modules 231, 232, 233, 234 may be provided to simulate a respective one of the control devices 111, 112, 113, 114, wherein each of the simulation modules 231, 232, 233, 234 executes the software of the respective control device 111, 112, 113, 114 to be simulated. In the course of this, the simulation modules 231, 233, 233, 234 each perform the respective predetermined actions at the predetermined action time points according to the determined action events.

A fourth function or module block 240 is used for determining or extrapolating a future or next action and the action time point thereof, in order to then provide said action time point for the time schedule. For this purpose, an extrapolation module 241 is provided as a fourth software module of the simulation software 205 and determines action time points of future, in particular next or subsequent, actions.

The scheduling module 211 and the action module 221 as well as the action module 221 and the simulation modules 231, 232, 233, 234 are in each case in connection with one another via interfaces. For this purpose, the first module block 210 and the second module block 220 thus comprise a corresponding interface 215 and 225, respectively, via which the scheduling module 211 is in data transmission connection with the action module 221. The second module block 220 furthermore comprises a second interface 226. Furthermore, a respective interface 235, 236, 237, 238 is provided for each of the simulation modules 231, 232, 233, 234. Via this second interface 226 and via these interfaces 235, 236, 237, 238 of the third module block 230, the action module 221 is in data transmission connection with the individual simulation modules 231, 232, 233, 234.

Likewise, the scheduling module 211 and the extrapolation module 241 as well as the extrapolation module 241 and the simulation modules 231, 232, 233, 234 are in each case in connection with one another via interfaces. For this purpose, the first module block 210 and the fourth module block 240 thus comprise a corresponding interface 215 and 245, respectively, via which the scheduling module 211 is in data transmission connection with the extrapolation module 241. The fourth module block 240 furthermore comprises a second interface 246. Furthermore, a respective interface 235, 236, 237, 238 is provided for each of the simulation modules 231, 232, 233, 234. Via this second interface 246 and via these interfaces 235, 236, 237, 238 of the third module block 230, the extrapolation module 241 is in data transmission connection with the individual simulation modules 231, 232, 233, 234.

In this example, while the interfaces of the first and third module blocks are used for connection to both the second and the fourth module block, the first and/or the third module block can each comprise further interfaces that can be used individually for the connection to the second or fourth module block.

According to a particularly preferred embodiment of the present invention, the simulation of the first computing unit 100 takes place according to a “functional mock-up interface” (FMI), which defines a standardized interface, in order to couple different simulation software or a plurality of different software models or software modules to one another and assemble them into an overall model or an overall simulation.

Expediently, the individual interfaces 215, 225, 226, 235, 236, 237, 238, 245, 246 are each provided as corresponding FMI interfaces. Furthermore, the individual software modules 211, 221, 231, 232, 233, 234, 241 are each designed according to a “functional mock-up unit” (FMU), in particular respectively as software containers, which, for example, comprise an XML file for defining variables, as well as formulas defined as C functions, and further data, such as parameter tables, user interface, documentation, etc., which are required in the respective software module for the simulation of the first computing unit 100.

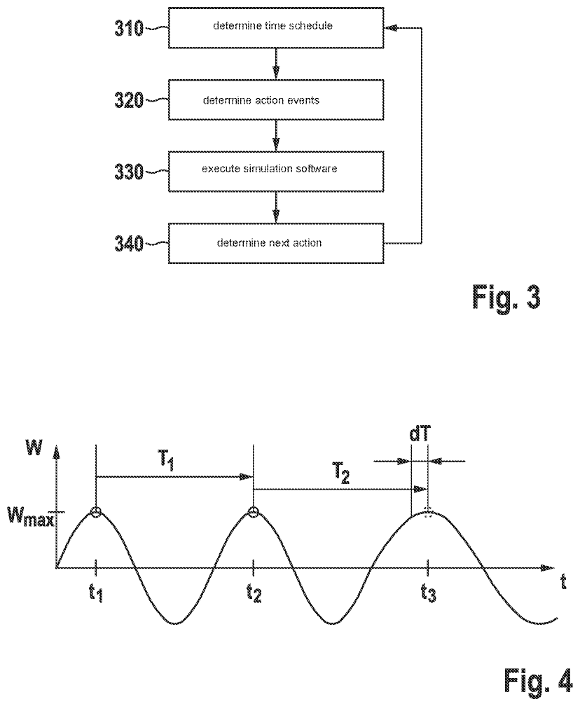

FIG. 3 shows a preferred embodiment of the method according to the present invention as a block diagram and is furthermore explained below with reference to FIGS. 1 and 2.

In a step 310, the scheduling module 211 determines the time schedule, in particular depending on the particular hardware components of the first computing unit 100 to be simulated, in particular on the components, such as processor, memory, etc., installed in the individual control devices 111, 112, 113, 114.

The time schedule in particular describes the order and processing times or latencies of the individual software processes. In particular, the schedule describes when the individual processes are started and fully processed and when results or outputs of individual processes are available, which in turn are required as inputs of further processes.

In a block 320, the action module 221 determines the action events, viz. depending on the time schedule according to which a predetermined action is to be performed at a respective predetermined action time point as part of the simulation of the hardware unit 100.

In a step 330, the individual simulation modules 231, 232, 233, 234 execute the respective software. For example, if the simulation module 231 is to perform a respective predetermined action at a predetermined action time point, action module 221 transmits a corresponding instruction via the interfaces 226 and 235 to said simulation module 231, in particular by means of a communication point according to the “functional mock-up interface.”

When carrying out the step 330, action results are obtained, e.g., data with values for the rotational speed or crankshaft angle. In a step 340, based on such an action result, an action time point of a future, in particular next, action is then determined. This action time point can then again be supplied to step 310; there, the time schedule is then re-determined or adjusted. This can thus in particular take place in a type of loop.

FIG. 4 schematically shows a further, preferred embodiment of the method according to the present invention, viz. by means of a time diagram in which an action result W, e.g., a value of a physical variable, such as a rotational speed, is plotted over the time t. An action is, for example, always to be performed at an action time point t₁, t₂, t₃, etc. An action time point is determined, for example, by a particular value, e.g., a maximum value Wₘₐₓ, of the action results or the physical variables.

If a current action time point is, for example, t₂, a next action time point t₃ can now be determined or estimated based on a time interval T₁ between the previous action time point t₁ and the current action time point t₂. In so doing, the time interval T₁ can, for example, be used as the basis, but so can, for example, a certain extrapolation logic according to which it is known, for example, that the rotational speed (if this is the physical variable or the action result) will become slower.

The time interval T₂ between the current action time point t₂ and the next current action time point t₃ will thus be longer than the time interval T₁ by the difference dT, for example. Based on this difference dT, the time schedule (for future action time points, next increments) can then be adjusted.

What is claimed is:

1. A method for simulating a first computing unit in a second computing unit, wherein software executed in the first computing unit to be simulated is executed in the second computing unit, the method comprising:
determining, by a scheduling module in the second computing unit, a time schedule according to which processes of the software are processed in the first computing unit to be simulated;
executing, by at least one simulation module in the second computing unit, the software for simulating the first computing unit, wherein the at least one simulation module performs a predetermined action at a respective predetermined action time point based on the time schedule in order to obtain an action result;
determining, based on the action result, an action time point of a future next action; and
using the determined action time point for the time schedule for generating a next increment in the schedule.

2. The method according to claim 1, wherein the action time point of the future action is furthermore determined based on an extrapolation logic of an extrapolation module in the second computing unit.

3. The method according to claim 1, further comprising:
determining a difference of a time interval between a current action time point and the action time point of the future action, and a time interval between a previous action time point and the current action time point; and
using the difference for the time schedule for generating the next increment.

4. The method according to claim 1, wherein the action result includes output data of the first computing unit to be simulated, including a rotational speed and/or a crankshaft angle of an internal combustion engine.

5. The method according to claim 1, wherein the scheduling module determines the time schedule depending on hardware components of the first computing unit to be simulated.

6. The method according to claim 1, wherein the predetermined actions includes reading in data and/or writing data and/or starting processing of a process.

7. The method according to claim 1, further comprising:
determining, by an action module in the second computing unit, action events depending on the time schedule according to which a predetermined action is to be performed at a respective predetermined action time point as part of the simulation of the first computing unit;
wherein the at least one simulation module performs the respective predetermined action at the predetermined action time points according to the determined action events.

8. The method according to claim 1, wherein the first computing unit to be simulated is a control device of a vehicle or a group of control devices, of the vehicle.

9. A computing unit configured to simulate a first computing unit in a second computing unit, wherein software executed in the first computing unit to be simulated is executed in the second computing unit, the computing unit configured to:
determine, by a scheduling module in the second computing unit, a time schedule according to which processes of the software are processed in the first computing unit to be simulated;
execute, by at least one simulation module in the second computing unit, the software for simulating the first computing unit, wherein the at least one simulation module performs a predetermined action at a respective predetermined action time point based on the time schedule in order to obtain an action result;
determine, based on the action result, an action time point of a future next action; and
use the determined action time point for the time schedule for generating a next increment in the schedule.

10. A non-transitory machine-readable storage medium on which is stored a computer program simulating a first computing unit in a second computing unit, wherein software executed in the first computing unit to be simulated is executed in the second computing unit, the computer program, when executed by a computer, causing the computer to perform the following steps:
determining, by a scheduling module in the second computing unit, a time schedule according to which processes of the software are processed in the first computing unit to be simulated;
executing, by at least one simulation module in the second computing unit, the software for simulating the first computing unit, wherein the at least one simulation module performs a predetermined action at a respective predetermined action time point based on the time schedule in order to obtain an action result;
determining, based on the action result, an action time point of a future next action; and
using the determined action time point for the time schedule for generating a next increment in the schedule.
